(19) United States
(12) Patent Application Publication
(10) Pub. No.: US 2026/0351496 A1
(43) Pub. Date: Nov. 5, 2026

(54) DEAD TANK HIGH-VOLTAGE CIRCUIT BREAKER HAVING AN ELECTRODE FOR MEASURING THE VOLTAGE AT ITS HIGH-VOLTAGE TERMINAL AND METHOD FOR MEASURING VOLTAGE WITH THE ELECTRODE

(71) Applicant: Siemens Energy Global GmbH & Co. KG, München (DE)

(72) Inventor: Radu-Marian Cernat, Berlin (DE)

(21) Appl. No.: 19/487,626

(22) PCT Filed: May 2, 2024
(86) PCT No.: PCT/EP2024/062080

§ 371 Date: Nov. 25, 2025

(30) Foreign Application Priority Data
May 24, 2023 (DE) 10 2023 204 819.1

(51) Int. Cl. H01H 33/02; G01R 15/04; H01H 33/53

(52) U.S. Cl. CPC H01H 33/027; G01R 15/04; H01H 33/53

(57) ABSTRACT

A dead tank high-voltage circuit breaker includes a housing, at least one feed-through in the housing for an electrical conductor and at least one electrode for shielding the electrical conductor from the housing. The at least one electrode is at floating potential and is configured to measure the voltage at a high-voltage terminal of the dead tank high-voltage circuit breaker. A method for measuring voltage with the electrode is also provided.

Dead Tank High-Voltage Circuit Breaker Having an Electrode for Measuring the Voltage at its High-Voltage Terminal and Method for Measuring Voltage with the Electrode The invention relates to a dead tank high-voltage circuit breaker having a housing and at least one feed-through in the housing for an electrical conductor, and having at least one electrode for shielding the electrical conductor from the housing. The invention also relates to a method for measuring voltage at the dead tank high-voltage circuit breaker.

Dead tank high-voltage circuit breakers are used to switch voltages and currents in the range of up to 1200 kV of voltage and in a range of up to several thousands ampere current. Breaker units in a dead tank, that is in a grounded housing, e.g., made of metals such as cast iron or steel, are designed to close and/or open, i.e. switch, a current path. The housing is filled with an insulating gas, e.g., SF₆ and/or clean air. A breaker unit comprises, e.g., at least one nominal current contact and at least one arcing contact, or a vacuum switch tube having particularly two contact pieces. Switching the contacts causes arcing which may be quenched by blowing switching gas, e.g., via a blowing nozzle made of Teflon and/or plastic, or die down in vacuum. Upon switching, the movable contacts of the breaker unit are moved via a drive. Drives are, e.g., spring-loaded drives, motors and/or manual drives. For example, a drive is attached to the housing of the dead tank high-voltage circuit breaker. For example, the housing is positioned on a frame in a building or in the open air.

For example, the dead tank high-voltage circuit breaker turns power lines, loads such as machines, power generators and/or parts of power grids on and/or off. Power lines are connected to the dead tank high-voltage circuit breaker via contact flanges, wherein a respective power flange is electrically connected to the breaker unit via an electrical conductor, e.g., in the form of a bus bar in a feed-through. The feed-throughs are disposed on the housing of the dead tank high-voltage circuit breaker. The electrical conductors are each routed outwards from the housing via the feed-throughs.

In order to avoid electrical flashover between the electrical conductors and the housing, e.g., made of metal, electrodes are disposed, e.g., in the region of the feed-throughs in the housing of the dead tank high-voltage circuit breaker. The electrodes are fixedly electrically connected to the ground potential for shielding the live conductors. In the prior art, voltage tapping or measuring at the electrodes is not provided, cf. particularly DE 19856775A1. Separate devices, such as inductive voltage transformers and/or capacitive voltage dividers, are used for measuring voltage in high-voltage grids. The separate devices for measuring voltage are associated with additional costs and occupancy of space in the span or at the dead tank. A measurement signal is transmitted in an analog manner from the devices to the measuring station, where it is processed and used for controlling the dead tank high-voltage circuit breaker.

The object of the invention is to indicate an improved dead tank high-voltage circuit breaker having an electrode for measuring the voltage at its high-voltage terminal and method for measuring voltage with the electrode, particularly having low costs and/or a reduced footprint compared to measuring voltage with separate measuring devices.

According to the invention, the object is achieved by a dead tank high-voltage circuit breaker with the features of claim 1 and/or by a method for measuring the voltage at a dead tank high-voltage circuit breaker, particularly a dead tank high-voltage circuit breaker described above, according to claim 11. Advantageous forms of the dead tank high-voltage circuit breaker according to the invention and/or the method according to the invention for measuring the voltage at a dead tank high-voltage circuit breaker, particularly a dead tank high-voltage circuit breaker described above, are indicated in the dependent claims. Subject matters of the main claim are combinable with features of the dependent claims and features of the dependent claims are combinable with one another.

A dead tank high-voltage circuit breaker according to the invention comprises a housing and at least one feed-through in the housing for an electrical conductor, and at least one electrode for shielding the electrical conductor from the housing. The at least one electrode is at floating potential. Due to the at least one electrode not being at ground potential, but at floating potential, a voltage of a high-voltage terminal of the dead tank high-voltage circuit breaker or the voltage at the electrical conductor disposed in the feed-through with the at least one electrode may be measured at the at least one electrode. This results in omitting an additional measuring device, particularly a voltage transformer and/or a voltage divider, allowing for reducing costs and space. Space in the span and/or at the dead tank for an additional measuring device is reduced. This enables a compact design.

The at least one electrode may be disposed in the at least one feed-through, particularly an open-air feed-through. The advantages described above are associated therewith.

At least one breaker unit may be disposed in the housing, which is connected to at least two electrical conductors each routed through a feed-through from the housing, particularly for applying high voltage in the range greater than and/or equal to 52 kilovolts. This may allow for measuring a voltage at one or both electrical conductors and testing the functionality of the at least one breaker unit, particularly the on and off switching state. Depending on the occurrence of overvoltage at the electrical conductors, switching the breaker unit may also be performed. The voltages measured may be processed directly on-site or in a control room following transmission, and/or may be used for regulating or controlling the power grid and/or the breaker unit.

The at least one electrode may be configured to be electrically isolated from the housing and may be electrically connected to ground potential via particularly discrete capacitances. With the at least one electrode being at floating potential, which is configured to be electrically isolated from the housing and electrically connected to the ground potential via discrete capacitances, the stray capacitance between conductor and electrode forms a voltage divider with the discrete capacitances, which may be employed for measuring the high-voltage potential.

An electrical circuit having at least one voltage divider may be comprised for measuring a high-voltage potential at the electrical conductor, wherein the voltage divider may comprise the particularly discrete capacitances and at least one stray capacitance between the electrical conductor and the at least one electrode. This allows for a simple and cost-effective manner to measure, via the electrode, a voltage of a high-voltage terminal of the dead tank high-voltage circuit breaker or the voltage at the electrical conductor disposed in the feed-through with the at least one electrode.

The electrical circuit for measuring a high-voltage potential may comprise elements for overvoltage protection, particularly for protecting connected measurement technology. This allows for effective protection from irreversible destruction in case of overvoltage peaks.

The voltage divider may be designed, particularly having a transformation, such that a low voltage is applied to the particularly discrete capacitances with a high-voltage applied to the dead tank high-voltage circuit breaker, particularly a low voltage in the range of up to 1000 volts. The transformation of the voltage divider may be selected such that a small voltage typical for further processing is applied to the discrete capacitances. The increase in potential of the electrode compared to the housing is negligible such that the occurring electrical field strengths at the highly loaded elements of the dead tank high-voltage circuit breaker do not change significantly and the functionality of the electrode is maintained.

By connecting the modified potential of the electrode, a non-conventional voltage transformer is integrated in the dead tank high-voltage circuit breaker. Thus, measuring the voltage at each high-voltage terminal of the circuit breaker is available, allowing for functions and loads to be monitored permanently. Occurring overvoltages are sensed, allowing for additional data to be available for further examination. For example, measurements of temporarily occurring overvoltages may be used in an aging model for high-voltage isolation.

The dead tank high-voltage circuit breaker may be designed for switching in the range greater than or equal to 52 kV, that is for high voltages.

The at least one electrode may be disposed particularly cylindrically around the respective electrical conductor in a contactless manner, particularly symmetrically. This results in a good opportunity for measuring voltage without any voltage flashovers and voltage rises particularly at the electrode and/or the housing, and a compact design of the dead tank high-voltage circuit breaker is possible. The at least one electrode, particularly made of copper, aluminum and/or steel, may be fixed to an isolator of the respective feed-through, particularly made of ceramic, silicon and/or a composite material, and/or to the housing of the dead tank high-voltage circuit breaker, particularly a metallic tank, particularly fixed using screws, welds, clips and/or adhesive, electrically isolated from the housing which may be connected to the ground potential. This allows for a compact, mechanical and temporally stable design.

A method according to the invention for measuring a voltage at a dead tank high-voltage circuit breaker described above comprises the at least one electrode for shielding the electrical conductor from the housing at a floating potential measuring, particularly continuously, a voltage at a high-voltage terminal of the dead tank high-voltage circuit breaker.

An overvoltage may be detected by measuring the voltage at the high-voltage terminal of the dead tank high-voltage circuit breaker.

The occurrence of an overvoltage and/or its temporal course may be used to determine aging of a high-voltage isolation of the dead tank high-voltage circuit breaker.

The advantages of the method according to the invention for measuring the voltage at a dead tank high-voltage circuit breaker according to claim 11 described above are analog to the advantages of the dead tank high-voltage circuit breaker according to the invention according to claim 1 described above, and vice versa.

In the following, exemplary embodiments of the invention are schematically illustrated in the figures and described in more detail below.

In the figures:

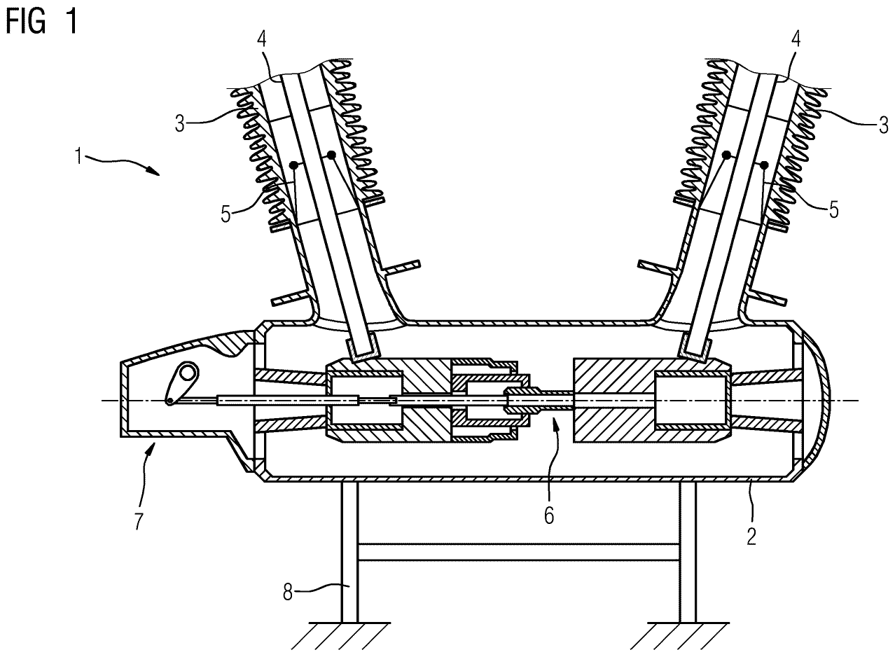

FIG. 1 schematically shows a sectional view of a dead tank high-voltage circuit breaker 1 according to the invention, having a housing 2 and two feed-throughs 3 in the housing 2 for electrical conductors 4, wherein the conductors 4 are each surrounded by an electrode 5 for shielding at floating potential, and

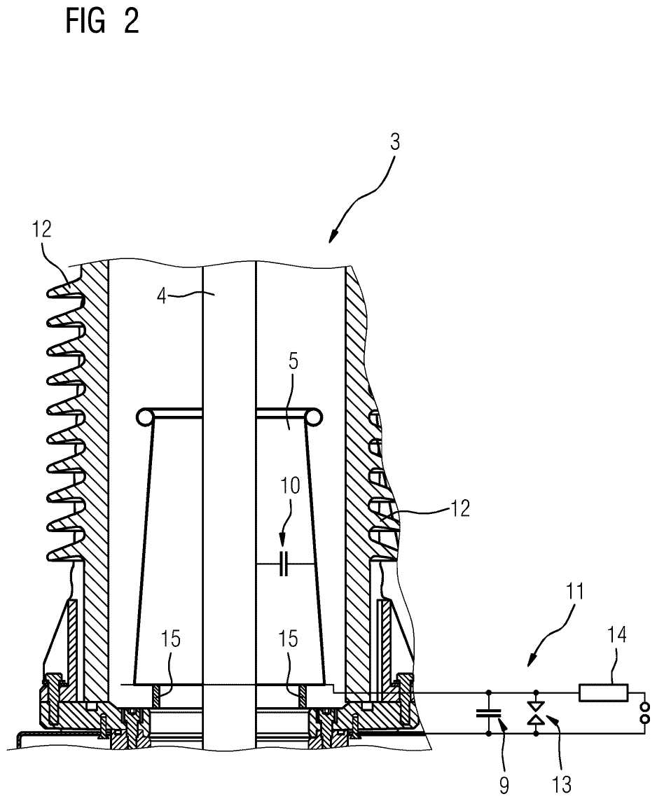

FIG. 2 schematically shows an enlarged sectional view of the electrode 5 in a feed-through 3.

FIG. 1 schematically shows a sectional side view of a dead tank high-voltage circuit breaker 1 according to the invention. In the embodiment of FIG. 1, the dead tank high-voltage circuit breaker 1 comprises a housing 2 with two feed-throughs 3 disposed on the housing 2. At least one breaker unit 6 for breaking and/or closing at least one current path is disposed in the housing 2. The breaker unit 6 is connected to terminals via electrical conductors 4, e.g., to an electrical power grid, power generators, power storage devices, electrical loads, and/or high-voltage lines. The electrical conductors 4 are each spatially encompassed by a feed-through 3 to electrically connect the breaker unit 6 inside the housing 2 to the electrical terminals outside the housing 2 via the electrical conductors 4.

The housing 2 of the dead tank high-voltage circuit breaker 1 is a metal housing, for example, particularly made of steel, cast iron and/or aluminum. The particularly tank-like housing 2 is disposed on and/or fixed to a frame 8, positioned in a building or in the open air. Particularly, the tank is designed to have a cylindrical shape and to be gas-tight, for example. The housing 2 is filled with an insulating gas, e.g., SF₆, CO₂ and/or purified, dried air, i.e., clean air.

The breaker unit 6 is disposed in the housing 2. The breaker unit 6 comprises, e.g., at least one typical circuit breaker with nominal current contact pieces and arcing contact pieces, and/or at least one vacuum switch tube. The movable contact pieces of the breaker unit 6 are driven via a drive 7, e.g., a motor, a crank, and/or a spring-loaded drive. The drive 7 is disposed in the housing 2, for example, or in an external housing on the housing 2 and/or on the frame 8, and mechanically connected to the movable con-2 tact pieces via elements of a kinematic chain, such as a transmission and/or a switch rod.

The feed-throughs 3 are fixed, e.g., screwed, welded, glued and/or clamped, to the housing 2, e.g., via flanges, particularly in a gas-tight manner. The conductors 4 electrically connected to the breaker unit 6 are routed outwards through the feed-throughs 3 from inside the housing 2. The feed-throughs are designed to be gas-tight, and are filled with an insulating gas, e.g., SF₆, CO₂ and/or purified, dried air, i.e., clean air. The feed-throughs 3 comprise, e.g., an isolator 12, particularly made of ceramic, silicon and/or a composite material. The isolator 12 is designed to have, e.g., a cylindrical shape, with ridges on the external surface for extending leakage current paths. The feed-through 3 is designed to be open towards the housing 2 and is designed to be closed in a gas-tight manner on the opposite side, with conductors 4 routed outwards toward the external terminals.

At least one conductor 4 in the feed-through 3 is disposed at a distance from the isolator 12, e.g., congruent to the cylinder axis of the isolator 12, and is comprised at least in a region spatially at a distance from the electrode 5. Conductors 4 are made of, e.g., copper, aluminum, and/or electrically well conductive steel, and/or are designed to have a rod or bus bar shape. The electrodes 5 are made of, e.g., copper, aluminum, and/or electrically well conductive steel, having a cylindrical shape or frustoconical shape, for example. Conductor 4, isolator 12 and electrode 5 of a respective feed-through 3 are disposed, e.g., on a congruent axis representing the respective longitudinal axis of the conductor 4, isolator 12 and electrode 5. The electrode 5 is disposed at a distance from the conductor 4 and the isolator 12, fixed in the isolator 12, spatially encompassing the conductor 4, e.g., to the isolator 12 via electrically isolating spacers or standoffs 15, as shown in FIG. 1, or to the tank housing 2 of the dead tank high-voltage circuit breaker 1, as shown in the exemplary embodiment of FIG. 2.

Otherwise, the exemplary embodiments of FIGS. 1 and 2 are the same, wherein FIG. 2 schematically shows an enlarged sectional view of an electrode 5 in an associated feed-through 3. The electrode 5 is at floating potential and is disposed at a distance around the associated conductor 4 for electrically shielding it.

By disposing the electrode 5 at a distance around the electrical conductor 4, at floating potential and not at ground potential, a voltage of a high-voltage terminal of the dead tank high-voltage circuit breaker 1 and the conductor 4, respectively, is measurable directly at the at least one electrode 5. This may result in omitting an additional measuring device, particularly a voltage transformer and/or a voltage divider outside the dead tank high-voltage circuit breaker, allowing for reducing costs and space. This allows for a compact design.

The electrode 5 at floating potential is electrically isolated from the housing 2 and is coupled to the ground potential via at least one discrete capacitance 9. A stray capacitance 10 between the electrode 5 and associated electrical conductor 4 forms a voltage divider with the at least one discrete capacitance 9, which is used for measuring the high-voltage potential at the electrical conductor 4. In order to protect a connected measurement technology, e. g., an overvoltage protection 13 is integrated in the measuring tap on the dead tank high-voltage circuit breaker 1. The transformation of the voltage divider is selected, e.g., such that a voltage typical for further processing is applied to the at least one discrete capacitance 9, particularly in the range of below one volt and up to one volt, and/or in the range of one volt to several hundreds volts. Thus, the increase in potential of the electrode 5 compared to the housing 2 is negligible such that the occurring electrical field strengths at the electrically highly loaded parts or elements of the dead tank high-voltage circuit breaker 1 do not change significantly and the shielding functionality of the electrode 5 for the conductor 4 is maintained.

The electrical circuit 11 described above further comprises, e.g., a terminating resistor 14, particularly in the range of several ohms to several megaohms, for measuring voltage via the at least one discrete capacitance 9. By connecting the modified potential of the electrode 5 at floating potential and disposed at a distance around the conductor 4, a non-conventional voltage transformer is integrated in the dead tank high-voltage circuit breaker 1.

In case of a corresponding design at each conductor 4 in a corresponding feed-through 3, measuring the voltage at each high-voltage terminal of the dead tank high-voltage circuit breaker 1 is available, allowing for functions and loads to be monitored permanently. Occurring overvoltages are sensed, such that additional data are available for further processing. For example, measurements of temporally occurring overvoltages may be used for an aging model of the high-voltage isolation. Monitoring and controlling and/or regulating switching the dead tank high-voltage circuit breaker 1 or connected high-voltage lines and/or devices is enabled.

The measuring data may be processed locally and/or may be sent, e.g., in a wireless or wired manner, particularly via the intranet and/or internet, to a central control room and/or data processing apparatuses. There, the data may be stored, processed and/or used for controlling, or for predictive maintenance, for example.

The exemplary embodiments described above may be combined with one another and/or may be combined with the prior art. Multiple breaker units 6 may be disposed, e.g., in a housing 2 of a dead tank high-voltage circuit breaker 1. These may be electrically interconnected and/or connected via at least two or more conductors 4, e.g., in feed-throughs 3, particularly via external terminals, to high-voltage conductors and/or grids, loads and/or power generators. Further high-voltage apparatuses, such as switching resistors, may be provided in the housing 2 or on the housing 2, e.g., in separate housings. An electrode 5 for measuring voltage may be provided around a conductor 4, or multiple electrodes, e.g., at different locations in the feed-through and/or the housing 2, and/or outside the housing 2, e.g., in the open air. A dead tank high-voltage circuit breaker 1 may also comprise multiple housings, each of which having breaker units 6, feed-throughs 3, electrical conductors 4 and/or electrodes 5 at free potential.

### LIST OF REFERENCE NUMERALS

1 Dead tank high-voltage circuit breaker
2 Housing
3 Feed-through
4 Electrical conductor
5 Electrode
6 Breaker unit
7 Drive
8 Frame
9 Discrete capacitance
10 Stray capacitance
11 Electrical circuit
12 Isolator
13 Overvoltage protection
14 Terminal resistor
15 Isolating spacers

1-13. (canceled)

14. A dead tank high-voltage circuit breaker, comprising:
a housing;
an electrical conductor;
at least one feed-through disposed at said housing and receiving said electrical conductor; and
at least one electrode for shielding said electrical conductor from said housing, said at least one electrode being at floating potential.

15. The dead tank high-voltage circuit breaker according to claim 14, wherein said at least one electrode is disposed in said at least one feed-through.

16. The dead tank high-voltage circuit breaker according to claim 15, wherein said at least one feed-through is an open-air feed-through.

17. The dead tank high-voltage circuit breaker according to claim 14, which further comprises:
at least one breaker unit disposed in said housing;
said at least one feed-through including at least two feed-throughs;
said electrical conductor being one of at least two electrical conductors; and
said at least two electrical conductors each being routed through a respective one of said at least two feed-throughs from said housing and connected to said at least one breaker unit.

18. The dead tank high-voltage circuit breaker according to claim 17, wherein said at least two electrical conductors are configured for applying high voltage in a range greater than or equal to 52 kilovolts.

19. The dead tank high-voltage circuit breaker according to claim 14, wherein said at least one electrode is configured to be electrically isolated from said housing and is electrically connected to ground potential.

20. The dead tank high-voltage circuit breaker according to claim 19, which further comprises discrete capacitances connected between said at least one electrode and ground potential.

21. The dead tank high-voltage circuit breaker according to claim 20, which further comprises an electrical circuit having at least one voltage divider for measuring a high-voltage potential at said electrical conductor, said at least one voltage divider including said discrete capacitances and at least one stray capacitance connected between said electrical conductor and said at least one electrode.

22. The dead tank high-voltage circuit breaker according to claim 21, wherein said electrical circuit for measuring a high-voltage potential includes elements for overvoltage protection or for protecting connected measurement technology.

23. The dead tank high-voltage circuit breaker according to claim 21, wherein said at least one voltage divider is configured to cause or carries out a transformation causing a low voltage to be applied to said discrete capacitances with a high-voltage applied to the dead tank high-voltage circuit breaker.

24. The dead tank high-voltage circuit breaker according to claim 23, wherein the low voltage is in a range of up to 1000 volts.

25. The dead tank high-voltage circuit breaker according to claim 14, wherein the dead tank high-voltage circuit breaker is configured for switching in a range greater than or equal to 52 kV.

26. The dead tank high-voltage circuit breaker according to claim 14, wherein said electrical conductor is one of a plurality of electrical conductors, said at least one electrode includes a plurality of electrodes, and each of said electrodes is disposed around or cylindrically around or symmetrically around a respective one of said electrical conductors in a contactless manner.

27. The dead tank high-voltage circuit breaker according to claim 14, wherein said at least one feed-through includes an isolator, and said at least one electrode is fixed to at least one of said isolator or said housing and is electrically isolated from said housing connected to ground potential.

28. The dead tank high-voltage circuit breaker according to claim 27, wherein said at least one electrode is fixed to at least one of said isolator or said housing by at least one of screws, welds, clips or adhesive.

29. The dead tank high-voltage circuit breaker according to claim 27, wherein said housing is a metallic tank, said at least one electrode is made of at least one of copper, aluminum or steel, and said an isolator is made of at least one of ceramic, silicon or a composite material.

30. A method for measuring a voltage at a dead tank high-voltage circuit breaker, the method comprising:
providing the dead tank high-voltage circuit breaker according to claim 14; and
using said at least one electrode for shielding said electrical conductor from said housing at a floating potential to measure a voltage at a high-voltage terminal of the dead tank high-voltage circuit breaker.

31. The method according to claim 30, which further comprises measuring the voltage at the high-voltage terminal of the dead tank high-voltage circuit breaker continuously.

32. The method according to claim 30, which further comprises detecting an overvoltage by measuring the voltage at the high-voltage terminal of the dead tank high-voltage circuit breaker.

33. The method according to claim 32, which further comprises using at least one of an occurrence of an overvoltage or a temporal course of the overvoltage to determine aging of a high-voltage isolation of the dead tank high-voltage circuit breaker.
